(19) United States
(12) Patent Application Publication
(10) Pub. No.: US 2024/0014165 A1
(43) Pub. Date: Jan. 11, 2024

(54) SEMICONDUCTOR DEVICE WITH FIXING FEATURE ON WHICH BONDING WIRE IS DISPOSED

(71) Applicant: NANYA TECHNOLOGY CORPORATION, NEW TAIPEI CITY (TW)

(72) Inventor: WU-DER YANG, TAOYUAN CITY (TW)

(21) Appl. No.: 17/860,119

(22) Filed: Jul. 8, 2022

(51) Int. Cl. H01L 23/00; H01L 23/31

(52) U.S. Cl. CPC H01L 24/48; H01L 23/3128; H01L 2224/48227; H01L 2224/48992; H01L 2224/48997; H01L 2224/48091; H01L 2224/05647; H01L 2224/05684; H01L 2224/05639; H01L 2224/05644; H01L 2224/05676; H01L 2224/05678; H01L 2224/05655; H01L 2224/05663; H01L 2224/05673; H01L 2224/05624; H01L 2224/0568; H01L 2224/05657; H01L 24/05; H01L 2224/45147; H01L 2224/45139; H01L 2224/45144; H01L 2224/45155; H01L 2224/45124; H01L 24/45; H01L 2224/85399; H01L 24/85; H01L 2224/32225; H01L 24/32; H01L 2224/73265; H01L 24/73

(57) ABSTRACT

A semiconductor device and method for manufacturing the same are provided. The semiconductor device includes a substrate, an electronic component, a bonding wire, and a fixing feature. The electronic component is disposed on the substrate. The bonding wire includes a first terminal connected to the electronic component and a second terminal connected to the substrate. The fixing feature is disposed on the substrate. The bonding wire is at least partially disposed on the fixing feature.

### TECHNICAL FIELD

The present disclosure relates to a semiconductor device and method for manufacturing the same, and more particularly, to a semiconductor device including a fixing feature on which a bonding wire is disposed.

### DISCUSSION OF THE BACKGROUND

With the rapid growth of the electronics industry, integrated circuits (ICs) have achieved high performance and miniaturization. Technological advances in IC materials and design have produced generations of ICs in which each successive generation has smaller and more complex circuits.

Many techniques have been developed for integrating an electronic component and a substrate. For example, the electronic component and the substrate may be connected by a bonding wire. In order to prevent the bonding wire from being disposed against the corner of the electronic component, the bonding wire is lengthened, increasing the size of the semiconductor device and resistance thereof. Therefore, a new semiconductor device and method of improving such problems is required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, an electronic component, a bonding wire, and a fixing feature. The electronic component is disposed on the substrate. The bonding wire includes a first terminal connected to the electronic component and a second terminal connected to the substrate. The fixing feature is disposed on the substrate. The bonding wire is at least partially disposed on the fixing feature.

Another aspect of the present disclosure provides another semiconductor device. The semiconductor device includes a substrate, an electronic component, a bonding wire, and a fixing feature. The electronic component is disposed on the substrate. The bonding wire includes a first terminal connected to the electronic component and a second terminal connected to the substrate. The fixing feature is disposed on an upper surface of the substrate. The bonding wire exceeds a lateral surface of the electronic component.

Another aspect of the present disclosure provides a method of manufacturing a semiconductor device. The method includes providing a substrate. The method also includes attaching an electronic component to the substrate. The method further includes attaching a fixing feature to an upper surface of the electronic component. In addition, the method includes forming a bonding wire connecting the substrate and the electronic component. The bonding wire is at least partially disposed on the fixing feature.

In embodiments of the present disclosure, the semiconductor device may include a fixing feature utilized to fix at least a portion of a bonding wire. The fixing feature may physically separate the bonding wire from a corner of an electronic component. As a result, electronic shorts may be prevented. Further, the length of the bonding wire may be reduced, resulting in a relatively small semiconductor device and relatively low resistance of the bonding wire.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is atop view of a semiconductor device, in accordance with some embodiments of the present disclosure.

FIG. 1B is a cross-sectional view along line A-A′ of the semiconductor device as shown in FIG. 1A, in accordance with some embodiments of the present disclosure.

FIG. 2 is a cross-sectional view of a semiconductor device, in accordance with some embodiments of the present disclosure.

FIG. 3 is a cross-sectional view of a semiconductor device, in accordance with some embodiments of the present disclosure.

FIG. 4 is a cross-sectional view of a semiconductor device, in accordance with some embodiments of the present disclosure.

FIG. 5 is a flowchart illustrating a method of manufacturing a semiconductor device, in accordance with some embodiments of the present disclosure.

FIG. 6A illustrates one or more stages of an exemplary method for manufacturing a semiconductor device according to some embodiments of the present disclosure.

FIG. 6B illustrates one or more stages of an exemplary method for manufacturing a semiconductor device according to some embodiments of the present disclosure.

FIG. 6C illustrates one or more stages of an exemplary method for manufacturing a semiconductor device according to some embodiments of the present disclosure.

FIG. 6D illustrates one or more stages of an exemplary method for manufacturing a semiconductor device according to some embodiments of the present disclosure.

FIG. 6E illustrates one or more stages of an exemplary method for manufacturing a semiconductor device according to some embodiments of the present disclosure.

FIG. 6F illustrates one or more stages of an exemplary method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

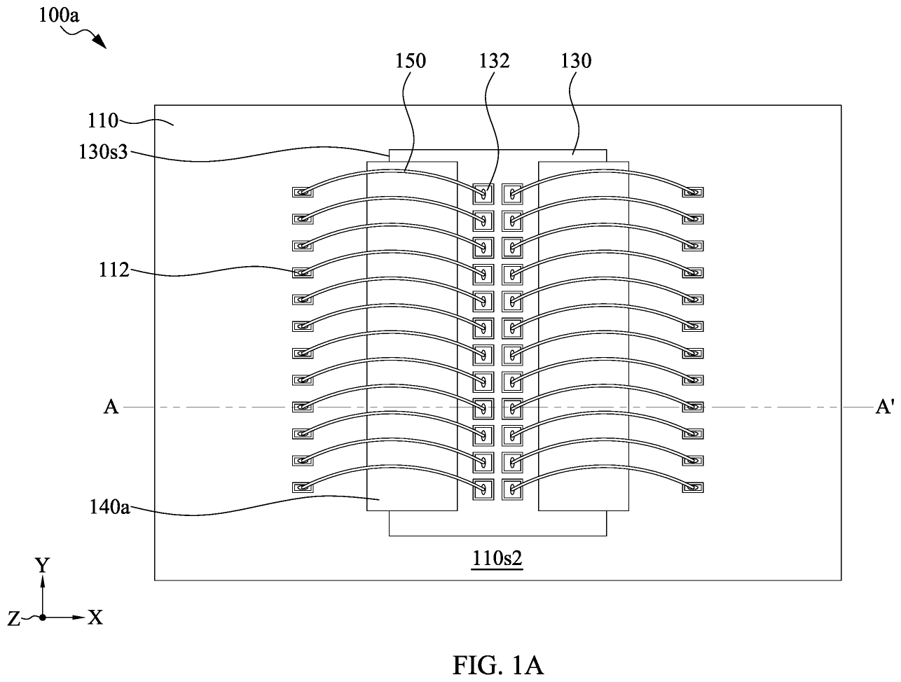

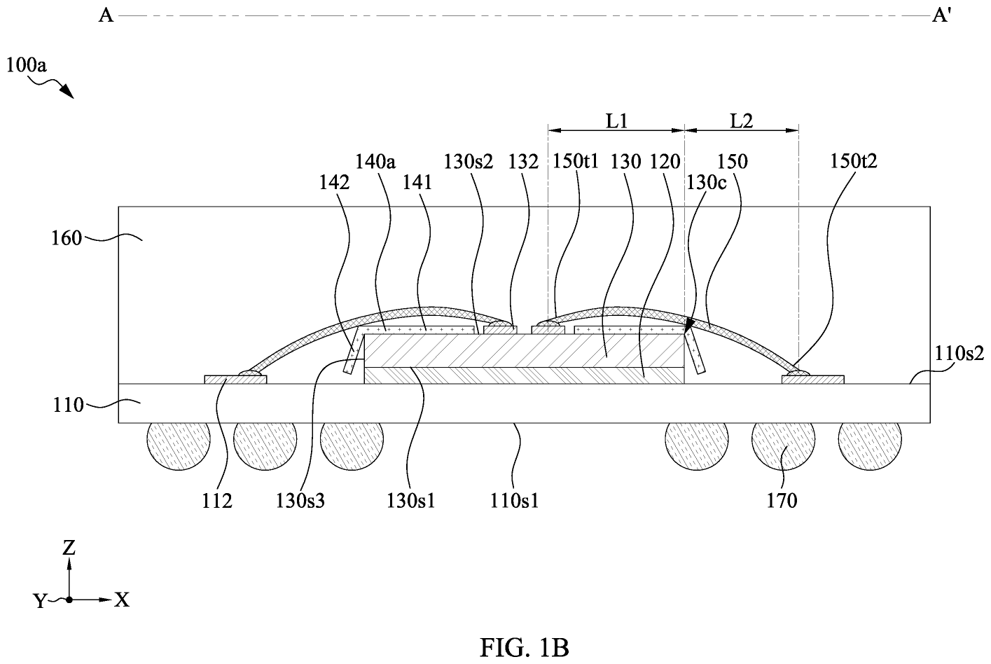

FIG. 1A and FIG. 1B illustrate a semiconductor device 100a, in accordance with some embodiments of the present disclosure, wherein FIG. 1A is a top view, and FIG. 1B is a cross-sectional view along line A-A′ of FIG. 1A.

In some embodiments, the semiconductor device 100a may include a substrate 110. In some embodiments, the substrate 110 may be or include, for example, a printed circuit board (PCB), such as a paper-based copper foil laminate, a composite copper foil laminate, or a polymer-impregnated glass-fiber-based copper foil laminate.

In some embodiments, the substrate 110 may include a surface 110s1 and a surface 110s2 opposite to the surface 110s1. In some embodiments, the surface 110s1 may also be referred to as a lower surface. In some embodiments, the surface 110s2 may also be referred to as an upper surface.

In some embodiments, the substrate 110 may include conductive pad(s), trace(s), via(s), layer(s), or other interconnection(s). For example, the substrate 110 may include one or more transmission lines (e.g., communications cables) and one or more grounding lines and/or grounding planes. For example, the substrate 110 may include one or more conductive pads (e.g., 112) in proximity to, adjacent to, or embedded in and exposed by the surface 110s1 and/or the surface 110s2 of the substrate 110.

In some embodiments, the semiconductor device 100a may include an adhesive layer 120. In some embodiments, the adhesive layer 120 may be disposed on the surface 110s2 of the substrate 110. The adhesive layer 120 may include, for example, an optical clear adhesive (OCA) or other suitable materials.

In some embodiments, the semiconductor device 100a may include an electronic component 130. In some embodiments, the electronic component 130 may be disposed on the surface 110s2 of the substrate 110. In some embodiments, the electronic component 130 may be attached to the surface 110s2 of the substrate 110 through the adhesive layer 120.

In some embodiments, the electronic component 130 may include a memory device, such as a dynamic random access memory (DRAM) device, a one-time programming (OTP) memory device, a static random access memory (SRAM) device, or other suitable memory devices. In some embodiments, the electronic component 130 may include a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices) or other devices. In some embodiments, the electronic component 130 may also include a passive device, such as a capacitor, an inductor, or other suitable passive devices.

The electronic component 130 may have a surface 130s1 and a surface 130s2 opposite to the surface 130s1. In some embodiments, the surface 130s1 may also be referred to as a backside surface or a lower surface. In some embodiments, the surface 130s2 may also be referred to as an active surface or an upper surface. As used herein, the term “active surface” may refer to a surface on which terminals are disposed for transmitting and/or receiving signals, such as input/output signals. In some embodiments, the surface 130s1 of the electronic component 130 may face the surface 110s2 of the substrate 110. The electronic component 130 may have a surface 130s3 (or a lateral surface) extending between the surfaces 130s1 and 130s2 of the electronic component 130. The electronic component 130 may have a corner 130c, which may be defined by the surfaces 130s2 and 130s3.

In some embodiments, the electronic component 130 may include conductive pads 132. The conductive pad 132 may be disposed on the surface 130s2 of the electronic component 130. In some embodiments, the conductive pad 132 may include metal, such as copper (Cu), tungsten (W), silver (Ag), gold (Au), ruthenium (Ru), iridium (Ir), nickel (Ni), osmium (Os), ruthenium (Rh), aluminum (Al), molybdenum (Mo), cobalt (Co), alloys thereof, combinations thereof or other suitable materials.

In some embodiments, the semiconductor device 100a may include a fixing feature 140a. In some embodiments, the fixing feature 140a may be configured to provide an area, such as a surface, an edge, or a corner, on which a bonding wire (or a conductive wire) is disposed. In some embodiments, the fixing feature 140a may be configured to fix at least a portion of the fixing feature 140a. In some embodiments, the fixing feature 140a may be utilized to physically separate the fixing feature 140a from the electronic component 130. In some embodiments, the fixing feature 140a may be utilized to physically separate the fixing feature 140a from the corner 130c of the electronic component 130. In some embodiments, the fixing feature 140a may include an electrically insulative material.

In some embodiments, the fixing feature 140a may be disposed on or over the surface 110s2 of the substrate 110. In some embodiments, the fixing feature 140a may be disposed on or over the surface 130s2 of the electronic component 130. In some embodiments, the fixing feature 140a may extend beyond the surface 130s3 of the electronic component 130. In some embodiments, the fixing feature 140a may cover the corner 130c of the electronic component 130. In some embodiments, the fixing feature 140a may be in contact with the corner 130c of the electronic component 130.

The fixing feature 140a may have a portion 141 and a portion 142. The portion 141 of the fixing feature 140a may be disposed on or over the surface 130s2 of the electronic component 130. The portion 142 of the fixing feature 140a may be free from vertically overlapping the surface 130s2 of the electronic component 130. In some embodiments, the fixing feature 140a may be disposed against the surface 130s2 and/or surface 130s3 of the electronic component 130. As used herein, the term “X is disposed against Y” may mean that X imposes a force or a stress, in addition to or other than a gravitational force, on Y.

In some embodiments, the portion 141 of the fixing feature 140a may be in contact with the surface 130s2 of the electronic component 130. In some embodiments, the portion 142 of the fixing feature 140a may be spaced apart from the surface 130s2 of the electronic component 130. In some embodiments, the portion 142 of the fixing feature 140a may be spaced apart from the surface 130s3 of the electronic component 130. In some embodiments, the portion 142 of the fixing feature 140a may be spaced apart from the surface 110s2 of the substrate 110. In some embodiments, the portion 142 of the fixing feature 140a may be angled to or slanted with respect to the surface 130s3 of the electronic component 130. In some embodiments, the portion 142 of the fixing feature 140a may be angled to the surface 110s2 of the substrate 110. In some embodiments, the portion 142 of the fixing feature 140a may extend across the surface 130s3 of the electronic component 130. In some embodiments, the portion 142 of the fixing feature 140a may partially overlap the adhesive layer 120 along an X-axis.

In some embodiments, the semiconductor device 100a may include bonding wire(s) 150. In some embodiments, each of the bonding wires 150 may have a terminal 150t1 connected to (or bonded to) the surface 130s2 of the electronic component 130 and a terminal 150t2 connected to (or bonded to) the surface 110s2 of the substrate 110. In some embodiments, the terminal 150t1 of the bonding wire 150 may be bonded to the conductive pad 132 of the electronic component 130. In some embodiments, the terminal 150t2 of the bonding wire 150 may be bonded to the conductive pad 112 of the substrate 110. In some embodiments, the fixing feature 140a may be disposed between the terminals 150t1 and 150t2 of the bonding wire 150. In some embodiments, the bonding wire 150 may include metal, such as copper (Cu), silver (Ag), gold (Au), nickel (Ni), aluminum (Al), alloys thereof, combinations thereof, or other suitable materials.

In some embodiments, the bonding wire 150 may be disposed on the fixing feature 140a. In some embodiments, the bonding wire 150 may be partially disposed on the fixing feature 140a. In some embodiments, the bonding wire 150 may partially contact the fixing feature 140a. In some embodiments, the bonding wire 150 may be disposed against the fixing feature 140a. In some embodiments, the bonding wire 150 may be disposed against the fixing feature 140a so that a force or a stress may be imposed on the electronic component 130 via the corner 130c of the electronic component 130.

The terminal 150t1 of the bonding wire 150 and the surface 130s3 of the electronic component 130 may have a length L1, along the X-axis, therebetween. The terminal 150t2 of the bonding wire 150 and the surface 130s3 of the electronic component 130 may have a length L2, along the X-axis, therebetween. In some embodiments, the length L1 may substantially equal or exceed the length L2. In some embodiments, a ratio between the length L1 and the length L2 may range from about 1 to about 3, such as 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, or 3.

When the ratio between the lengths L1 and L2 ranges from about 1 to about 3, the vertical length of the bonding wire 150 may be reduced, which thereby reduces the size of the semiconductor device 100a. Further, as the length of the bonding wire 150 decreases, the resistance of the bonding wire is correspondingly reduced.

As shown in FIG. 1A, multiple bonding wires 150 may share a common fixing feature 140a. In some embodiments, the fixing feature 140a may be in contact with a plurality of bonding wires 150. In some embodiments, the bonding wire 150 may extend along the X-axis. In some embodiments, the fixing feature 140a may extend along the Y-axis.

In some embodiments, the semiconductor device 100a may include an encapsulant 160. In some embodiments, the encapsulant 160 may be disposed on the surface 110s2 of the substrate 110. In some embodiments, the encapsulant 160 may cover the surface 110s2 of the substrate 110. In some embodiments, the encapsulant 160 may encapsulate the fixing feature 140a. In some embodiments, the fixing feature 140a may be spaced apart from the surface 130s3 of the electronic component 130 by the encapsulant 160. In some embodiments, the encapsulant 160 may encapsulate the bonding wire 150. The encapsulant 160 may include insulative or dielectric material. In some embodiments, the encapsulant 160 may be made of molding material that may include, for example, a Novolac-based resin, an epoxy-based resin, a silicone-based resin, or other suitable encapsulant. Suitable fillers may also be included, such as powdered SiO₂.

In some embodiments, the semiconductor device 100a may include electrical connections 170. The electrical connection 170 may be disposed on the surface 110s1 of the substrate 110. In some embodiments, the electrical connection 170 may be configured to electrically connect the semiconductor device 100a and an external device (not shown). In some embodiments, the electrical connection 170 may include solder material, such as alloys of gold and tin solder or alloys of silver and tin solder.

In a comparative example, bonding wires are connected between an electronic component and a substrate without a fixing feature. In such condition, the length of the bonding wire should be greater than a predetermined value in order to prevent the bonding wire from being disposed against the corner of the electronic component. If not, the bonding wire may be prone to breakage due to relatively high tension. Further, the contact between the corner of the electronic component and the bonding wire may result in electrical shorts. Therefore, the comparative example may have a relatively large width. In embodiments of the present disclosure, the bonding wires may be separated from the corner of the electronic component by a fixing feature. Further, the length of the bonding wire may be reduced, resulting in a relatively small size of the semiconductor device and relatively low resistance.

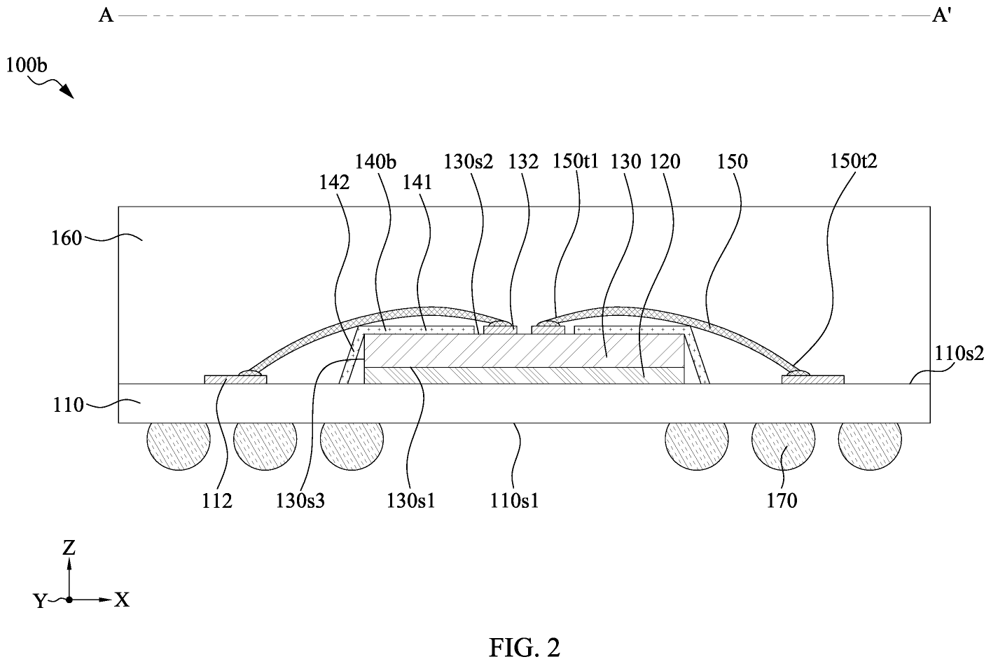

FIG. 2 is a cross-sectional view of a semiconductor device 100b, in accordance with some embodiments of the present disclosure. The semiconductor device 100b is similar to the semiconductor device 100a, with differences therebetween as follows.

In some embodiments, the semiconductor device 100b may include a fixing feature 140b. In some embodiments, the fixing feature 140b may be in contact with the surface 110s2 of the substrate 110. In some embodiments, the portion 142 of the fixing feature 140b may be in contact with the surface 110s2 of the substrate 110. In some embodiments, the fixing feature 140b may be angled with respect to a normal direction (e.g., Y-axis) of the surface 110s2 of the substrate 110. In some embodiments, the portion 142 of the fixing feature 140b may be angled with respect to the normal direction of the surface 110s2 of the substrate 110.

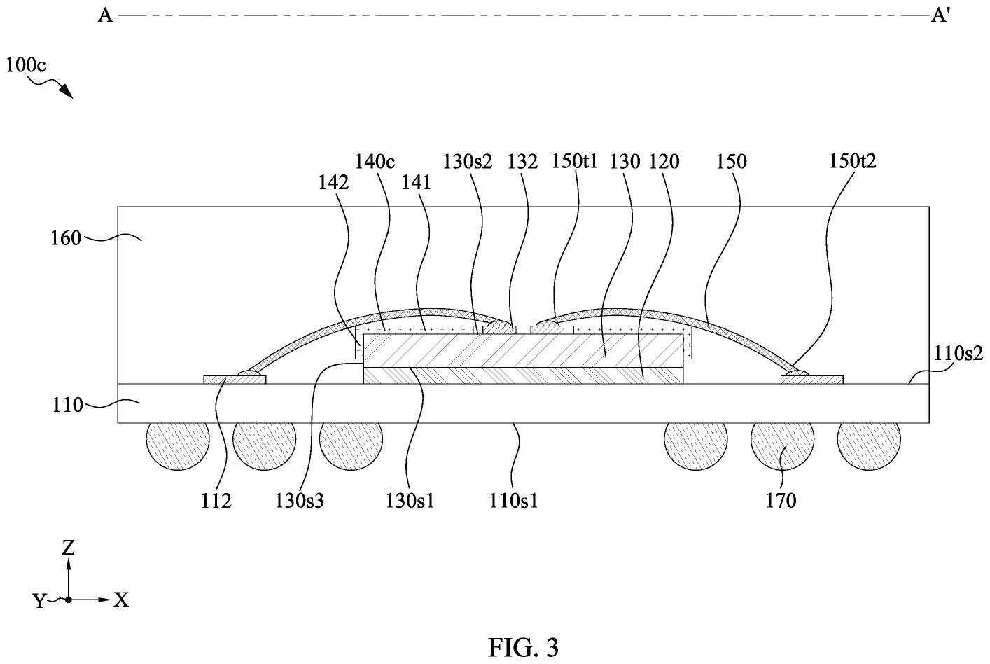

FIG. 3 is a cross-sectional view of a semiconductor device 100c, in accordance with some embodiments of the present disclosure. The semiconductor device 100c is similar to the semiconductor device 100a, with differences therebetween as follows.

In some embodiments, the semiconductor device 100c may include a fixing feature 140c. In some embodiments, the fixing feature 140c may be conformally disposed on the surface 130s3 of the electronic component 130. In some embodiments, the fixing feature 140c may be in contact with the surface 130s3 of the electronic component 130. In some embodiments, the portion 142 of the fixing feature 140c may be in contact with the surface 130s3 of the electronic component 130. In some embodiments, a portion of the surface 130s3 of the electronic component 130 may be exposed by the fixing feature 140c. In some embodiments, a portion of the surface 130s3 of the electronic component 130 may be exposed by the portion 142 of the fixing feature 140c.

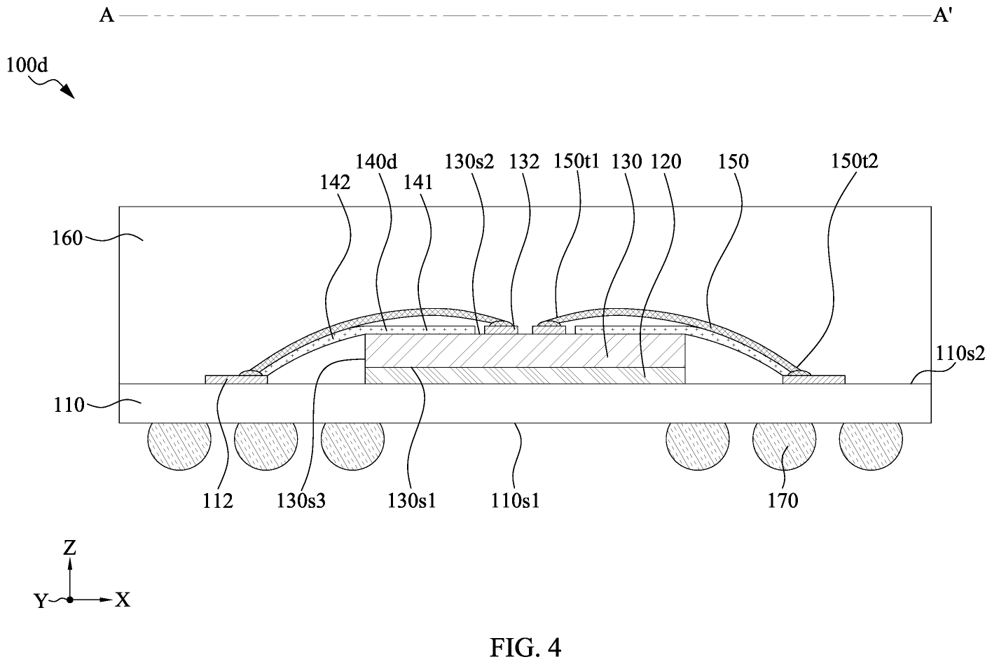

FIG. 4 is a cross-sectional view of a semiconductor device 100d, in accordance with some embodiments of the present disclosure. The semiconductor device 100d is similar to the semiconductor device 100a, with differences therebetween as follows.

In some embodiments, the semiconductor device 100d may include a fixing feature 140d. In some embodiments, the fixing feature 140d may extend between the terminal 150t1 of the bonding wire 150 and the terminal 150t2 of the bonding wire 150. In some embodiments, the fixing feature 140d may be in contact with the 112. In some embodiments, the fixing feature 140d may be on contact with the terminal 150t2 of the bonding wire 150. In some embodiments, the bonding wire 150 may be conformally disposed on the fixing feature 140d. In some embodiments, the bonding wire 150 may be conformally disposed on the portion 142 of the fixing feature 140d, and the bonding wire 150 may be spaced apart from the portion 142 of the fixing feature 140d.

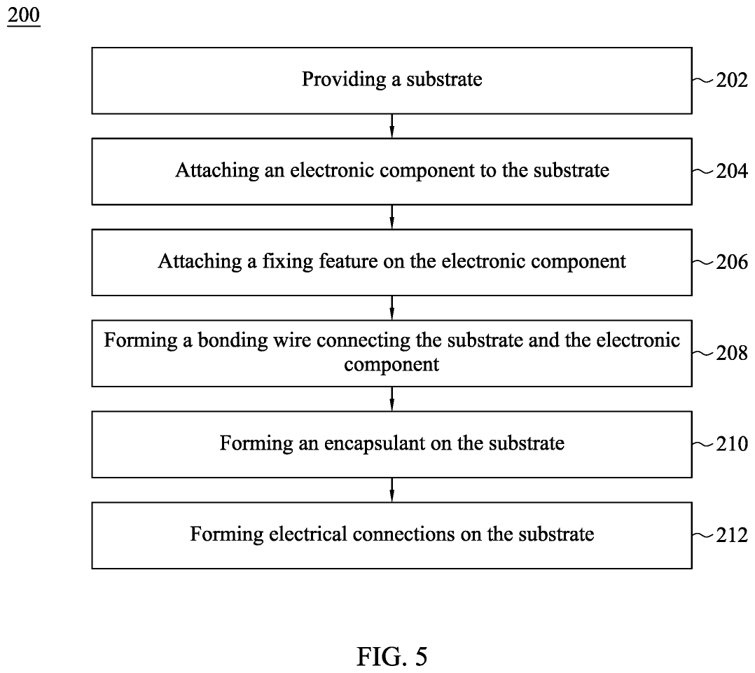

FIG. 5 is a flowchart illustrating a method 200 of manufacturing a semiconductor device, in accordance with some embodiments of the present disclosure.

The method 200 begins with operation 202 in which a substrate may be provided. The substrate may have a lower surface and an upper surface opposite to the lower surface. The substrate may include one or more conductive pads in proximity to, adjacent to, or embedded in and exposed by the lower surface and/or the upper surface of the substrate.

The method 200 continues with operation 204 in which an electronic component may be attached to the upper surface of the substrate. In some embodiments, the electronic component may be attached to the upper surface of the substrate by an adhesive layer. The electronic component may have a backside surface, an active surface, and a lateral surface extending between the backside surface and active surface of the electronic component. The electronic component may have a conductive pad on the active surface of the electronic component.

The method 200 continues with operation 206 in which a fixing feature may be formed over or attached to the upper surface of the electronic component. In some embodiments, the fixing feature may be in contact with the upper surface of the electronic component. In some embodiments, the fixing feature may extend beyond the lateral surface of the electronic component. In some embodiments, the fixing feature may be spaced apart from the lateral surface of the electronic component. In some embodiments, the fixing feature may be angled with respect to the lateral surface of the electronic component. In some embodiments, the fixing feature may cover a corner defined by the upper surface and lateral surface of the electronic component.

The fixing feature may have a first portion and a second portion. The first portion of the fixing feature may be disposed on or over the upper surface of the electronic component. The second portion of the fixing feature may be free from vertically overlapping the upper surface of the electronic component. In some embodiments, the second portion of the fixing feature may be spaced apart from the upper surface of the substrate. In some embodiments, the second portion of the fixing feature may be angled to the lateral surface of the electronic component. In some embodiments, the second portion of the fixing feature may extend across the lateral surface of the electronic component.

The method 200 continues with operation 208 in which a bonding wire may be formed. In some embodiments, the bonding wire may have a first terminal connected to the electronic component and a second terminal connected to the substrate. In some embodiments, the bonding wire may be at least partially disposed on the fixing feature. In some embodiments, at least a portion of the bonding wire may be in contact with the fixing feature. In some embodiments, the bonding wire may be disposed against the corner of the electronic component. In some embodiments, the bonding wire may be spaced apart from the corner of the electronic component through the fixing feature.

The method 200 continues with operation 210 in which an encapsulant may be formed on the upper surface of the substrate. In some embodiments, the encapsulant may encapsulate the electronic component, the fixing feature, and the bonding wire.

The method 200 continues with operation 212 in which electrical connections may be formed on the lower surface of the substrate, which thereby produces a semiconductor device.

The method 200 is merely an example, and is not intended to limit the present disclosure beyond what is explicitly recited in the claims. Additional operations can be provided before, during, or after each operation of the method 200, and some operations described can be replaced, eliminated, or reordered for additional embodiments of the method. In some embodiments, the method 200 can include further operations not depicted in FIG. 5. In some embodiments, the method 200 can include one or more operations depicted in FIG. 5.

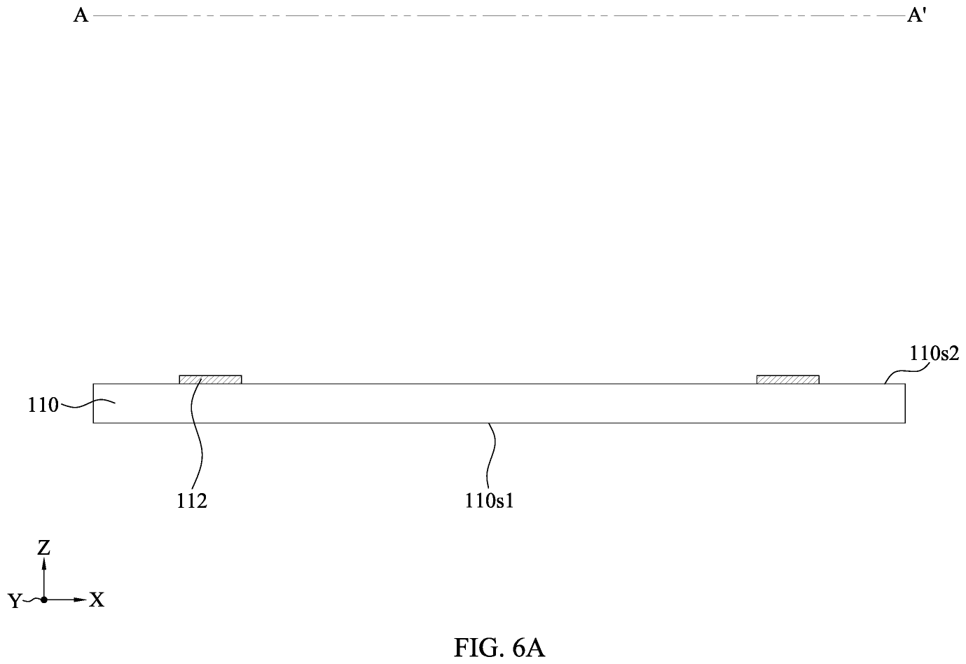

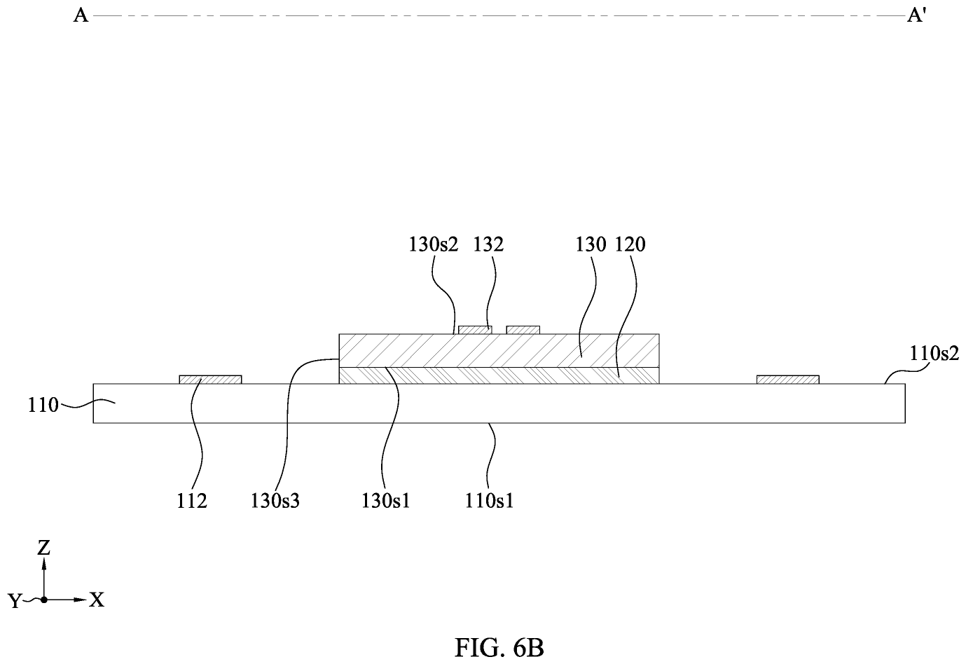

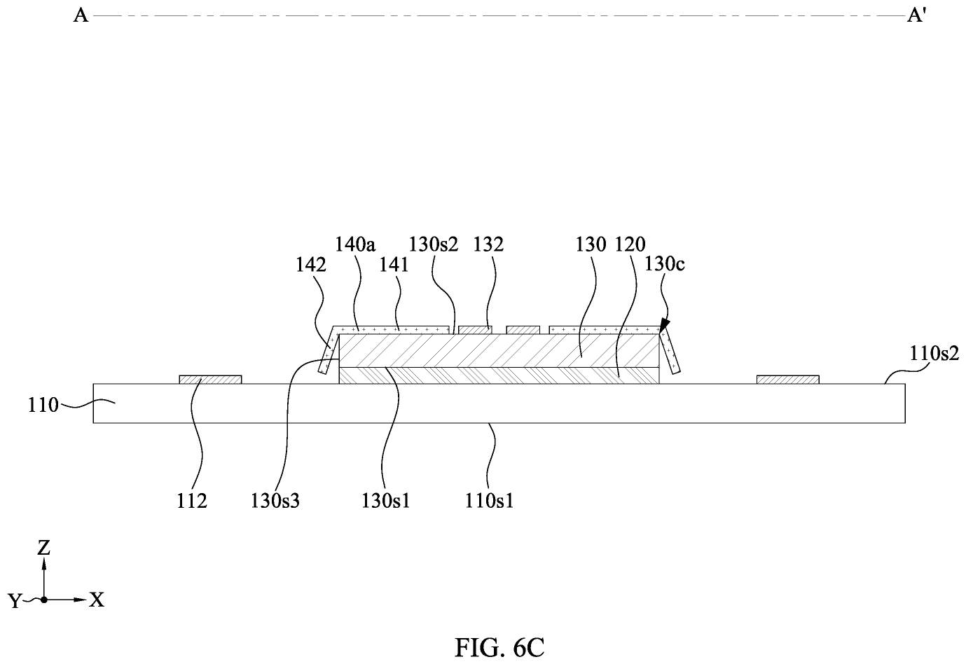

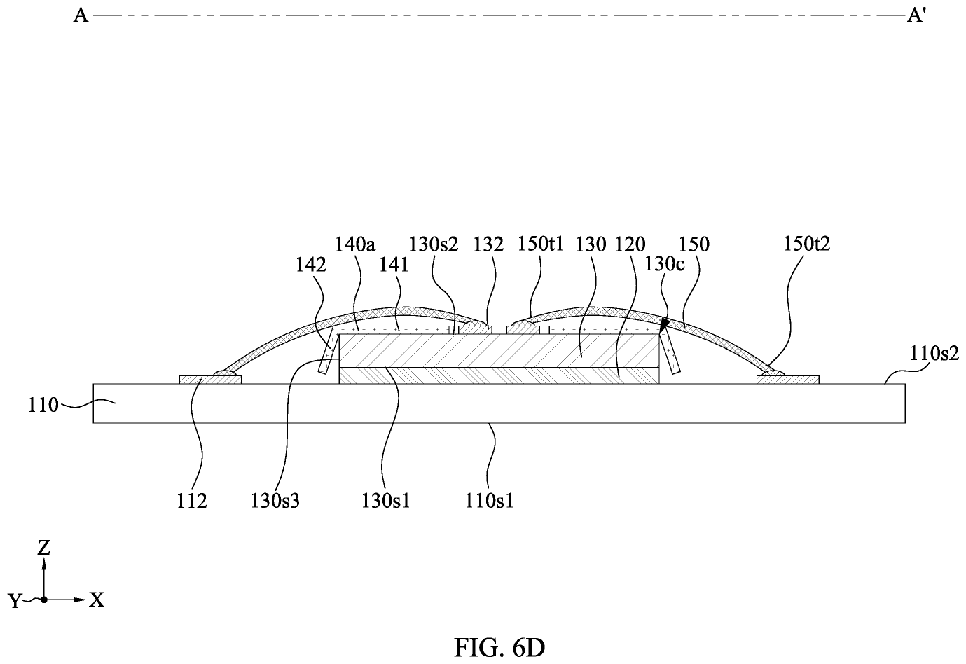

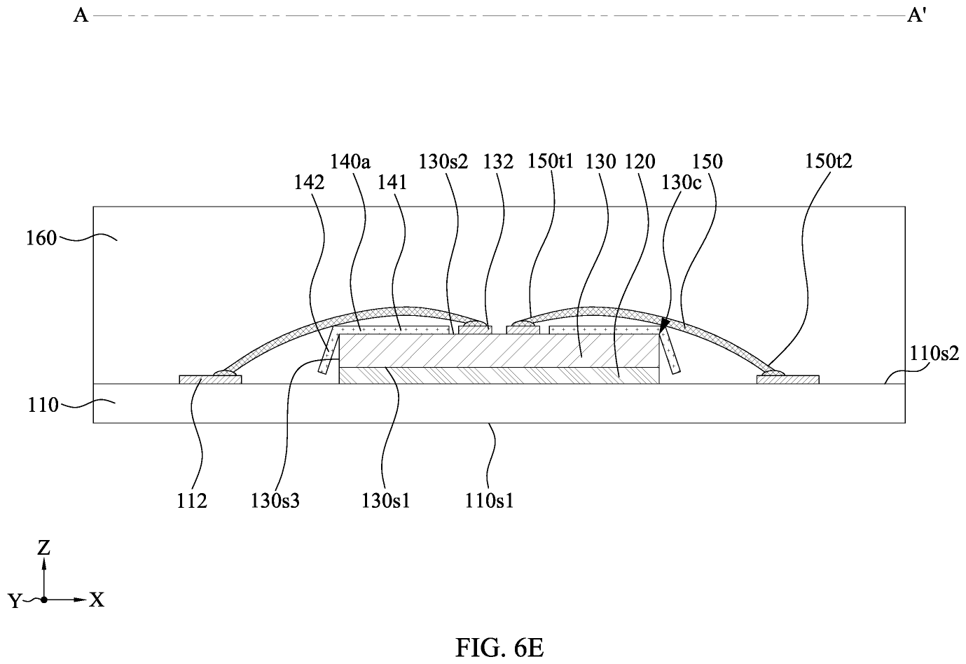

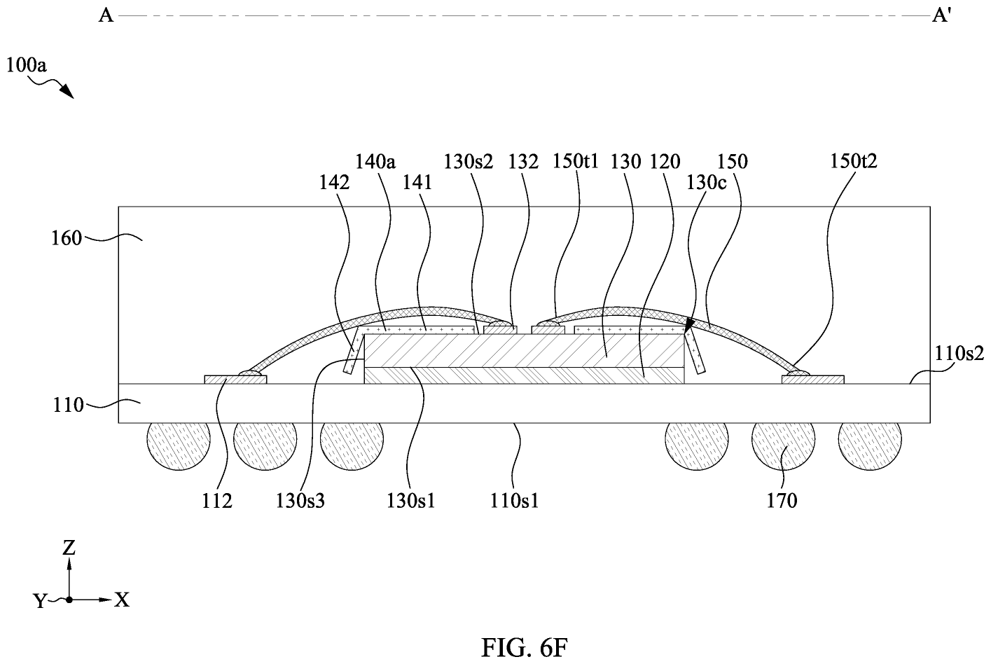

FIG. 6A-FIG. 6F illustrate one or more stages of an exemplary method for manufacturing a semiconductor device according to some embodiments of the present disclosure. In some embodiments, the semiconductor device 100a may be manufactured through the operations described with respect to FIG. 6A-FIG. 6F.

Referring to FIG. 6A, a substrate 110 may be provided. The substrate 110 may have a surface 110s1 and a surface 110s2 opposite to the surface 110s1. The substrate 110 may include one or more conductive pads (e.g., 112) in proximity to, adjacent to, or embedded in and exposed by the surface 110s1 and/or the surface 110s2 of the substrate.

Referring to FIG. 6B, an electronic component 130 may be formed on the surface 110s2 of the substrate 110. In some embodiments, the electronic component 130 may be attached to the surface 110s2 of the substrate 110 by an adhesive layer 120. The electronic component 130 may have a surface 130s1, a surface 130s2, and a surface 130s3 extending between the surfaces 130s1 and 130s2 of the electronic component 130. The electronic component 130 may have a conductive pad 132 on the surface 130s2 of the electronic component 130.

Referring to FIG. 6C, a fixing feature 140a may be formed over the surface 130s2 of the electronic component 130. In some embodiments, the fixing feature 140a may be in contact with the surface 130s2 of the electronic component 130. In some embodiments, the fixing feature 140a may extend beyond the surface 130s of the electronic component 130. In some embodiments, the fixing feature 140a may be spaced apart from the surface 130s3 of the electronic component 130. In some embodiments, the fixing feature 140a may be angled with respect to the surface 130s3 of the electronic component 130. In some embodiments, the fixing feature 140a may cover a corner 130c defined by the surfaces 130s2 and 130s3 of the electronic component 130.

The fixing feature 140a may have a portion 141 and a portion 142. The portion 141 of the fixing feature 140a may be disposed on or over the surface 130s2 of the electronic component 130. The portion 142 of the fixing feature 140a may be free from vertically overlapping the surface 130s2 of the electronic component 130 along the Y-axis. In some embodiments, the portion 142 of the fixing feature 140a may be spaced apart from the surface 110s2 of the substrate 110. In some embodiments, the portion 142 of the fixing feature 140a may be angled to the surface 130s3 of the electronic component 130. In some embodiments, the portion 142 of the fixing feature 140a may extend across the surface 130s3 of the electronic component 130.

Referring to FIG. 6D, a bonding wire 150 may be formed. In some embodiments, the bonding wire 150 may have a terminal 150t1 connected to the electronic component 130 and a terminal 150t2 connected to the substrate 110. In some embodiments, the bonding wire 150 may be at least partially disposed on the fixing feature 140a. In some embodiments, at least a portion of the bonding wire 150 may be in contact with the fixing feature 140a. In some embodiments, the bonding wire 150 may be disposed against the corner 130c of the electronic component 130. In some embodiments, the bonding wire 150 may be spaced apart from the corner 130c of the electronic component 130 through the fixing feature 140a.

Referring to FIG. 6E, an encapsulant 160 may be formed on the surface 110s2 of the substrate 110. The encapsulant 160 may be formed by a molding operation. In some embodiments, the encapsulant 160 may encapsulate the electronic component 130, the fixing feature 140a, and the bonding wire 150.

Referring to FIG. 6F, electrical connections 170 may be formed on the surface 110s1 of the substrate 110, which thereby produces the semiconductor device 100a. The electrical connection 170 may include a solder material.

It is contemplated that in FIG. 6C, if the fixing feature is in contact with the surface 110s2 of the substrate 110, a semiconductor device the same as or similar to the semiconductor device 100b as illustrated and described with reference to FIG. 2 can be formed.

It is contemplated that in FIG. 6C, if the fixing feature is in contact with the surface 130s3 of the electronic component 130, a semiconductor device the same as or similar to the semiconductor device 100c as illustrated and described with reference to FIG. 3 can be formed.

It is contemplated that in FIG. 6C, if the fixing feature extends from the conductive pad 112 to the conductive pad 132, a semiconductor device the same as or similar to the semiconductor device 100d as illustrated and described with reference to FIG. 4 can be formed.

In embodiments of the present disclosure, the semiconductor device may include a fixing feature utilized to fix a portion of a bonding wire. The fixing feature may physically separate the bonding wire from a corner of an electronic component. As a result, electronic shorts may be prevented. Further, the length of the bonding wire may be reduced, resulting in a relatively small semiconductor device and relatively low resistance of the bonding wire.

One aspect of the present disclosure provides a semiconductor device. The semiconductor device includes a substrate, an electronic component, a bonding wire, and a fixing feature. The electronic component is disposed on the substrate. The bonding wire includes a first terminal connected to the electronic component and a second terminal connected to the substrate. The fixing feature is disposed on the substrate. The bonding wire is at least partially disposed on the fixing feature.

Another aspect of the present disclosure provides another semiconductor device. The semiconductor device includes a substrate, an electronic component, a bonding wire, and a fixing feature. The electronic component is disposed on the substrate. The bonding wire includes a first terminal connected to the electronic component and a second terminal connected to the substrate. The fixing feature is disposed on an upper surface of the substrate. The bonding wire exceeds a lateral surface of the electronic component.

Another aspect of the present disclosure provides a method of manufacturing a semiconductor device. The method includes providing a substrate. The method also includes attaching an electronic component to the substrate. The method further includes attaching a fixing feature to an upper surface of the electronic component. In addition, the method includes forming a bonding wire connecting the substrate and the electronic component. The bonding wire is at least partially disposed on the fixing feature.

In embodiments of the present disclosure, the semiconductor device may include a fixing feature utilized to fix a portion of a bonding wire. The fixing feature may physically separate the bonding wire from a corner of an electronic component. As a result, electronic shorts may be prevented. Further, the length of the bonding wire may be reduced, resulting in a relatively small semiconductor device and relatively low resistance of the bonding wire.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
an electronic component disposed on the substrate;
a bonding wire comprising a first terminal connected to the electronic component and a second terminal connected to the substrate; and
a fixing feature disposed on the substrate, wherein the bonding wire is at least partially disposed on the fixing feature.

2. The semiconductor device of claim 1, wherein the fixing feature is spaced apart from a lateral surface of the electronic component.

3. The semiconductor device of claim 2, further comprising:
an encapsulant encapsulating the electronic component, wherein the fixing feature is spaced apart from the lateral surface of the electronic component by the encapsulant.

4. The semiconductor device of claim 1, wherein the fixing feature has a first portion over an upper surface of the electronic component and a second portion spaced apart from the upper surface of the electronic component.

5. The semiconductor device of claim 4, wherein the second portion of the fixing feature is slanted with respect to a lateral surface of the electronic component.

6. The semiconductor device of claim 4, wherein the second portion of the fixing feature is spaced apart from an upper surface of the substrate.

7. The semiconductor device of claim 4, wherein the second portion of the fixing feature is in contact with an upper surface of the substrate.

8. The semiconductor device of claim 4, wherein the second portion of the fixing feature is in contact with a lateral surface of the electronic component.

9. The semiconductor device of claim 4, wherein the bonding wire is conformally disposed on the second portion of the fixing feature.

10. The semiconductor device of claim 9, wherein the bonding wire is spaced apart from the first portion of the fixing feature.

11. The semiconductor device of claim 1, wherein the fixing feature extends from the first terminal of the bonding wire to the second terminal of the bonding wire.

12. The semiconductor device of claim 1, wherein the bonding wire is disposed against a corner of the electronic component, wherein the corner of the electronic component is defined by an upper surface and a lateral surface of the electronic component.

13. The semiconductor device of claim 1, wherein the fixing feature is in contact with an upper surface of the electronic component.

14. A semiconductor device, comprising:
a substrate;
an electronic component disposed on the substrate;
a bonding wire comprising a first terminal connected to the electronic component and a second terminal connected to the substrate; and
a fixing feature disposed on an upper surface of the substrate, wherein the bonding wire exceeds a lateral surface of the electronic component.

15. The semiconductor device of claim 14, wherein the fixing feature is spaced apart from the lateral surface of the electronic component.

16. The semiconductor device of claim 15, further comprising:
an encapsulant encapsulating the electronic component, wherein the fixing feature is spaced apart from the lateral surface of the electronic component by the encapsulant.

17. The semiconductor device of claim 14, wherein the fixing feature has a first portion over an upper surface of the electronic component and a second portion spaced apart from the upper surface of the electronic component.

18. The semiconductor device of claim 17, wherein the second portion of the fixing feature is slanted with respect to the lateral surface of the substrate.

19. The semiconductor device of claim 17, wherein the second portion of the fixing feature is spaced apart from an upper surface of the substrate.

20. The semiconductor device of claim 17, wherein the second portion of the fixing feature is in contact with the upper surface of the substrate.
